(19) United States
(12) Patent Application Publication
(10) Pub. No.: US 2003/0173673 A1
(43) Pub. Date: Sep. 18, 2003

(54) Method for distributed shielding and/or bypass for electronic device with three dimensional interconnection

(76) Inventor: Christian Val, St Remy Les Chevreuse (FR)

Correspondence Address: Lowe Hauptman, Gilman & Berner, Suite 310, 1700 Diagonal Road, Alexandria, VA, 22314, US

(21) Appl. No.: 10/333,855

(22) PCT Filed: Jul. 20, 2001
(86) PCT No.: PCT/FR01/02382

(30) Foreign Application Priority Data
Jul. 25, 2000 (FR) 00/09731

(51) Int. Cl. H01L 21/44; H01L 23/48; H01L 29/40

(52) U.S. Cl. 257/758; 438/598

(57) ABSTRACT

The invention relates to a process for the distributed shielding and decoupling of an electronic device having integrated components with three-dimensional interconnection, to such a device and to a production process.

The device comprises, associated with each active component (2), at least one capacitor plane formed from a thin sheet (10) of a dielectric, said sheet being metallized (10, 11, 12) on its two plane faces. The components and the capacitor planes are stacked in alternation and joined together to form a block (1′), the lateral faces (21 to 24) of which carry conductors (13, 14) ensuring 3D interconnection. The metallizations (11, 12) are delimited in order to be flush with the edges of the block only via tabs (110, 120). One of the metallizations (11) connected to ground serves as shielding.

The invention applies especially to the production of very compact memory blocks.

The present invention relates to a process for the distributed shielding and/or the decoupling of an electronic device having integrated electronic components stacked and joined together to constitute a three-dimensional interconnection block. It also relates to the device thus obtained and to a process for collectively obtaining these devices.

The production of current electronic systems, both civilian and military, must take into account the requirements for increasing compactness owing to the ever increasing number of circuits employed.

To take these requirements into account, it has already been proposed to produce stacks of bare integrated-circuit chips or packages that encapsulate chips, the interconnection taking place in three dimensions using the faces of the stack as interconnection surfaces for producing the necessary connections between output pins.

The evolution in integrated-circuit chips, as in the packages encapsulating them, is tending to make them ever thinner. This is directed toward constructions certainly tending toward a few microns to a few tens of microns in thickness. When it is desired to stack such circuits, their closeness results in increasingly problematic interference. Moreover, the search to obtain ever high operating frequencies implies ever improving decoupling of the voltage supplies for the various circuits. Customarily, a decoupling capacitor is provided, this being placed as close as possible to the circuits, for example directly on the stack of circuits, or beneath this stack or to one side, as close as possible. For extremely rapid switching, it is not enough to have sufficient stored energy, and therefore sufficient capacitance; it is also necessary to transfer this energy very quickly to the switched circuits and the problem, that is becoming serious, is that of the inductance presented by the connections of the capacitor to the circuits. The shorter the connections, the lower the inductance and the greater use that can be made of high frequencies.

A first object of the invention is to produce, in a simple and inexpensive manner, distributed shielding between the components in order to remedy the problem of mutual interference and of interference with the outside.

Another object of the present invention is to solve these two problems, of interference and of decoupling, in a combined manner.

One subject of the invention is a process for the distributed shielding and/or decoupling that eliminates the abovementioned drawbacks by the interposition of thin metallized sheets between the various circuits forming the three-dimensional stack.

The invention therefore provides a process for the distributed shielding and/or decoupling of an electronic device having integrated electronic components, in which said components, which have connection pads on their periphery, are stacked and joined together in order to constitute a three-dimensional interconnection block, characterized in that said process consists in inserting, between each component and the adjacent component, at least one separating plane consisting of a thin sheet of a dielectric, at least one face of which carries a metallization, said metallization being connected to ground in order to shield the adjacent component or components.

Preferably, each face of the separating planes is metallized in order to constitute capacitor planes, said metallizations of a plane being connected to ground and to the supply voltage of at least one of the adjacent components, respectively.

By virtue of this process, the metallizations connected to ground serve as perfect shielding between the components and the interposition of one or more capacitor planes associated with each component allows greatly improved decoupling because the length of the connections between capacitor and associated components is reduced to the minimum.

Another aspect of the invention, provides an electronic device having integrated electronic components with distributed shielding and/or decoupling, in which said components, which have connection pads on their periphery are stacked and joined together in order to constitute a three-dimensional interconnection block, characterized in that said device comprises an alternating stack of integrated electronic components and of separating planes in order to form said block, each plane comprising a thin sheet of a dielectric, said sheet being metallized on at least one of its two faces and the stack comprising at least one separating plane between two consecutive components, and in that the lateral faces of the block include conductors placed on at least one of the faces in order to connect the metallizations of the separating planes to the corresponding connection pads of the components.

Preferably, each plane is metallized on its two faces in order to constitute a capacitor plane.

Finally, such devices can be obtained more economically in that they can be produced collectively.

Thus, yet another aspect of the invention provides a process for collectively obtaining electronic devices as described hereinabove, characterized in that said process consists in:

producing said components side by side in a regular geometrical pattern within active planes;

producing said metallizations in the same geometrical pattern on thin sheets of a dielectric;

stacking and joining together said active planes and said metallized sheets in an alternating manner, at least one sheet being interposed between each active plane, so that the components and the metallizations are in mutual correspondence in order to define sawing lines delimiting said individual blocks;

piercing holes, perpendicular to said planes and sheets in the assembly obtained, along sawing lines directly in line with said connection tabs and said connection pads;

plating said holes; and

sawing the assembly along the sawing lines in order to obtain said blocks in which the three-dimensional interconnections consist of plated half-holes.

The invention will be more clearly understood and further features and advantages will become apparent from the description below and from the appended drawings in which:

FIG. 1 is a partial diagram of a known three-dimensional interconnection device;

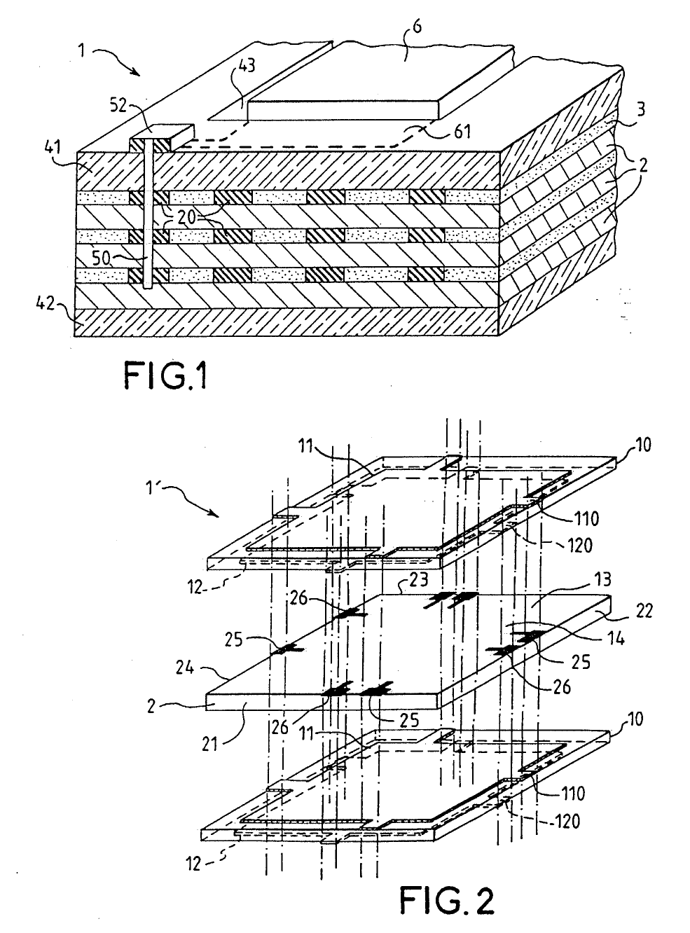

FIG. 2 is a partial exploded view of a device according to the invention;

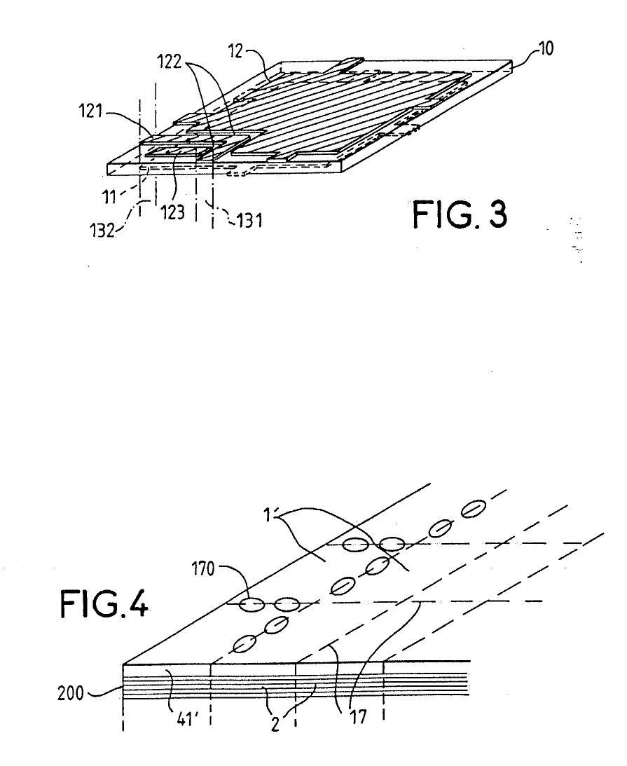

FIG. 3 is a diagram of a capacitor plane according to one embodiment of the invention;

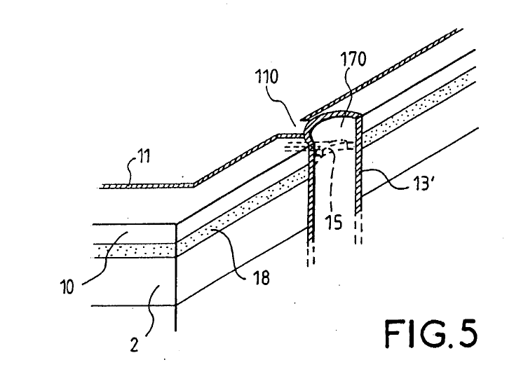

FIG. 4 is a partial view illustrating a collective production process according to the invention; and

FIG. 5 shows, partially, a device obtained according to the process illustrated by FIG. 4.

FIG. 1 shows, partially, a known three-dimensional interconnection electronic device consisting of a block 1 formed from semiconductor chips 2 stacked vertically by means of insulating and adhesive layers 3. Such a device is disclosed in French patent FR 2 645 681. Provided on top and below are closure layers 41 and 42 made of an insulating material, which make it possible in particular to protect and strengthen, if necessary, the block 1. The block 1 has, on one of its external faces, for example in an aperture 43 on the top face of the closure layer 41, a decoupling capacitor 6. The latter is connected via a conductor 61 to a connection pad 52 of the device. An interconnection conductor 50, which is placed on a lateral face of the block 1 and interconnects connection pads 20 of the chips 2, terminates in this pad 52.

As already mentioned, the length of the connections between the capacitor 6 and the chips 2 may be quite long, in particular in the case of the bottom chips 2 in the block, thereby constituting a serious drawback to operating at high speeds. Moreover, the thinner the chips 2 and the layers 3 become, in order to take up less room and also increase the speed, the greater and more problematic the interference between chips will become.

The invention stemmed from the observation that, technologically, it is known how to mass-produce multilayer capacitors from a very thin dielectric film, for example 1 to 2 μm in thickness, metallized on both faces and rolled up to form hundreds of layers from which the capacitors are then cut by sawing.

According to the invention, provision is therefore made to insert, between each chip or electronic component, whether bare or encapsulated in a package, at least one separating plane formed from a thin sheet of a dielectric, at least one face which carries a metallization, one of the metallizations being connected to ground, thereby shielding the adjacent components; if both faces are metallized, the other face is connected to a supply voltage for at least one of the adjacent components in order to produce a decoupling capacitor.

The term “electronic component” is understood to mean any bare or encapsulated chip or integrated circuit, whatever its complexity. As an example, this may be a memory plane on any active substance, made of silicon or other material.

FIG. 2 illustrates, partially, in an exploded view, the construction of a device according to the invention as defined above. Of the block 17 constituting this device, only a single electronic component 2 and the two capacitor planes flanking it in the alternating stack forming the block 1′ have been shown. The component 2 includes, on at least one of its faces, connection pads 25, 26 on its periphery (only those corresponding to the ground pads 25 and supply voltage pads 26 have been shown here). As an example, pads have been shown near all the lateral faces 21 to 24 of the block 1′, but this is not essential and it would be possible to provide them only near a single lateral face or several lateral faces.

The capacitor planes, which are placed on each side of the component 2, each consist of a thin sheet 10 of a dielectric, both the upper and lower faces of which are metallized. These upper 11 and lower 12 metallizations are delimited in order to be flush with the edges of the block 1′ only via connection tabs 110, 120. After the various elements of the block 1′ have been alternately stacked and joined together, for example by an adhesive and insulating material (not shown), the tabs 110, 120 and the pads 25, 26 are connected via respective conductors 13, 14 to the lateral faces of the block 1′, the conductors 13 being, for example, connected to ground and the conductors 14 to the supply voltage.

Of course, between each component and its neighbor, it is possible to use several capacitor planes in parallel instead of a single one, as in FIG. 2, so as to increase the capacitance.

Moreover, if two or more supply voltage levels are needed for one or more active components, here again it is necessary to provide two or more capacitor planes in order to connect their respective metallizations to these voltages via different conductors, such as 14.

The thin sheets 10 may have very small thicknesses, of the order of a few tenths of a micron to a few microns. It is possible to use as material polyethylene terephthalate, for example with a thickness of around 2 μm, or polyethylene naphthalate, for example with a thickness of around 0.9 μm.

The metallizations 11, 12 are made of aluminum, for example with a thickness of 0.3 μm, this having the advantage of being consistent with the aluminum conductors often used for the active components.

As in the case of the block in FIG. 1, a lower closure layer, carrying the external connection elements (pads, connections, with tabs, BGA, etc.), and an upper closure layer may be provided on the block 1′ using an organic sheet carrying, for example polarization markings.

It is clear that provision may be made to metallize only one face of the thin sheet 10, in this case the metallization 11, which is connected to ground; effective distributed shielding, without the capacitor function, is thus obtained.

Another advantage of the invention, illustrated by FIG. 3, is that it is possible to use one of the metallizations of a capacitor plane to send back or route certain connections from one side of the block to the other. To do this, a routing or linking connection conductor 121 connecting a conductor 131 on one lateral face of the block to a conductor 132 on an adjacent face, is etched (122) in the metallization, preferably the metallization 12 connected to a supply voltage. This conductor 121 is separated from the metallization 12, 123 by etching 122 obtained by any known means. The metallization portion 123 is not of any use, as it is not connected here. These linking conductors are preferably produced in the metallization 12 connected to the supply voltage. This is because only a fraction of the capacitance is thus lost, and this can be compensated for by an additional capacitor plane, whereas the shielding by the ground metallization 11 remains intact, which would not be obtained in the reverse case.

Of course, with the same technology as for the capacitor planes, it would be possible to add a topological plane with a metallization on a thin sheet from which various linking conductors would be cut.

The electronic devices of the type described above may be produced individually by alternately stacking the active components and the capacitive planes (optionally the closure layers), then by joining them together by adhesive or resin in order to form a block, and finally by producing the conductors on the lateral faces of the block, these steps constituting the essential production steps.

However, for economic reasons, it may be preferable to produce these devices collectively. To do this, as illustrated in FIG. 4, active planes 200 are provided in which active components 2 are produced side by side in a regular geometrical pattern (adjacent rectangles or squares). The metallizations of the capacitor planes are produced in the same geometrical pattern on thin sheets of a dielectric. The active planes and the metallized sheets are alternately stacked, optionally with closure layers such as 41′, and joined together so that the components and the metallizations are in mutual correspondence facing each other in order to define sawing lines 17 delimiting the individual blocks 1′. The assembly is pierced with holes 170 perpendicular to said planes and sheets, along the sawing lines 17 and vertically in line with the connection tabs and pads of each block. This piercing may be carried out by punching. The holes 170 are plated and then the block is sawn along the lines 17 so as to obtain the individual blocks with the three-dimensional interconnection conductors produced by the plated half-holes, as may be seen in the partial representation in FIG. 5.

This figure shows a plated half-hole 170, the metallization 13′ of which connects the tab 110 of the metallization 11 of capacitor plane (10, 11, 12) to the connection pad 15 of an active component 2. The adhesive layer 18 joins the component 2 to the capacitor plane.

It is clear that this collective production process can be carried out only because the thicknesses of the blocks are small and compatible with non-prohibitive hole diameters in order to obtain correct metallization.

One particularly advantageous method of implementation may consist in piercing oblong holes, the major axis of which follows the sawing lines, instead of circular holes. This has the advantage of encroaching less on the working area of the active components and on the metallizations and of increasing the alignment tolerances.

Of course, the invention can be applied to any type of component; it is particularly advantageous in the production of memory blocks with very thin memory planes.

1. A process for the distributed shielding and/or decoupling of an electronic device having integrated electronic components, in which said components, which have connection pads on their periphery, are stacked and joined together in order to constitute a three-dimensional interconnection block (1), characterized in that said process consists in inserting, between each component (2) and the adjacent component, at least one separating plane (10, 11, 12) consisting of a thin sheet (10) of a dielectric, at least one face of which carries a metallization (11, 12), said metallization being connected to ground in order to shield the adjacent component or components.

2. The process as claimed in claim 1, characterized in that each face of the separating planes is metallized in order to constitute capacitor planes, said metallizations (11, 12) of a plane being connected to ground and to the supply voltage of at least one of the adjacent components, respectively.

3. The process as claimed in claim 1 or 2, characterized in that the metallizations (11, 12) and the connection pads (25, 26) are connected by conductors (13, 14) placed on at least one of the lateral faces (21 to 24) of the block.

4. The process as claimed in one of claims 1 to 3, characterized in that the metallizations (11, 12) of the planes are delimited in order to be flush with the edge of the block only via connection tabs (110, 120) placed near at least one of the faces of the block, said conductors (13, 14) being placed so as to connect the said connection tabs to the corresponding connection pads of the components.

5. The process as claimed in any one of claims 1 to 4, characterized in that at least one separating plane or capacitor adjacent to it is associated with each component.

6. The process as claimed in any one of claims 2 to 5, characterized in that, to send back a connection (131, 132) from one face of the block to another, a linking conductor (121) is cut (122) in at least one capacitor plane metallization (12) connected to a supply voltage.

7. The process as claimed in any one of claims 1 to 6, characterized in that, in the stack constituting the block, at least one thin sheet of dielectric having at least one metallized face is added in order to constitute a topological plane for the routing of connections between the various lateral faces of the block.

8. An electronic device having integrated electronic components with distributed shielding and/or decoupling, in which said components, which have connection pads on their periphery, are stacked and joined together in order to constitute a three-dimensional interconnection block, characterized in that said device comprises an alternating stack of integrated electronic components (2) and of separating planes in order to form said block (1′), each plane comprising a thin sheet (10) of a dielectric, said sheet being metallized (11, 12) on at least one of its two faces and the stack comprising at least one separating plane between two consecutive components, and in that the lateral faces (21 to 24) of the block (1′) include conductors (13, 14) placed on at least one of the faces in order to connect the metallizations (11, 12) of the separating planes to the corresponding connection pads (25, 26) of the components.

9. The device as claimed in claim 8, characterized in that each plane is metallized on two faces (11, 12) in order to constitute a capacitor plane.

10. The device as claimed in claim 9, characterized in that the metallizations (11, 12) of the capacitor planes are delimited in order to be flush with the lateral faces of the block only via connection tabs (110, 120) placed toward at least one face of the block and in contact with said associated conductors (13, 14).

11. The device as claimed in one of claims 8 to 10, characterized in that, for each plane (10, 11, 12), said thin sheet (10) is made of polyethylene terephthalate or of polyethylene naphthalate.

12. The device as claimed in claim 11, characterized in that said thin sheet has a thickness ranging from a few tenths of a micron to several microns.

13. The device as claimed in either of claims 11 and 12, characterized in that said metallizations (11, 12) of the planes are made of aluminum and have a thickness of a few tenths of a micron.

14. The device as claimed in any one of claims 8 to 13, characterized in that said integrated electronic components (2) are memory planes.

15. The device as claimed in any one of claims 8 to 13, characterized in that said components consist of bare integrated-circuit chips.

16. The device as claimed in any one of claims 8 to 13, characterized in that said components consist of packages encapsulating integrated-circuit chips.

17. The device as claimed in any one of claims 8 to 16, characterized in that the various separating planes and/or capacitors and components of a block (1′) are joined together by adhesive or resin.

18. The device as claimed in any one of claims 8 to 17, characterized in that said block furthermore includes, on each side of the stack, a closure layer made of dielectric.

19. A process for collectively obtaining electronic devices as claimed in any one of claims 8 to 18, characterized in that said process consists in:
producing said components side by side in a regular geometrical pattern within active planes (200);
producing said metallizations in the same geometrical pattern on thin sheets of a dielectric;
stacking and joining together said active planes and said metallized sheets in an alternating manner at least one sheet being interposed between each active plane, so that the components and the metallizations are in mutual correspondence in order to define sawing lines (17) delimiting said individual blocks;
piercing holes (170), perpendicular to said planes and sheets in the assembly obtained, along sawing lines directly in line with said connection tabs (110, 120) and said connection pads (25,26);
plating said holes; and
sawing the block along the sawing lines (17) in order to obtain said blocks in which the three-dimensional interconnections consist of plated half-holes.

20. The process as claimed in claim 19, characterized in that said holes are produce by punching.
